(19) United States
(12) Patent Application Publication
(10) Pub. No.: US 2004/0256657 A1
(43) Pub. Date: Dec. 23, 2004

(54) [FLASH MEMORY CELL STRUCTURE AND METHOD OF MANUFACTURING AND OPERATING THE MEMORY CELL]

(76) Inventors: CHIH-WEI HUNG, HSIN-CHU (TW); CHENG-YUAN HSU, HSINCHU CITY (TW); CHI-SHAN WU, TAIPEI (TW); MIN-SAN HUANG, HSINCHU (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/250,286

(22) Filed: Jun. 20, 2003

(51) Int. Cl. H01L 29/788

(52) U.S. Cl. 257/315

(57) ABSTRACT

A flash memory cell structure is provided. The flash memory cell includes a substrate, a gate structure, a source region, an erase gate, an erase gate dielectric layer, a select gate, a select gate dielectric layer and a drain region. The gate structure is set up over the substrate. The gate structure includes a tunneling oxide layer, a floating gate, an inter-gate dielectric layer, a control gate and a spacer. The source region is formed in the substrate on one side of the gate structure. The erase gate is formed over the source region on one side of the gate structure. The erase gate dielectric layer is formed between the erase gate and the source region. The select gate is set up on another side of the gate structure. The select gate dielectric layer is formed between the select gate and the substrate. The drain region is formed in the substrate on one side of the select gate.

### BACKGROUND OF INVENTION

1. Field of Invention

The present invention relates to a memory cell device. More particularly, the present invention relates to a flash memory cell structure and a method of manufacturing and operating the memory cell.

2. Description of Related Art

Flash memory is a memory device that allows multiple data writing, reading and erasing operations. In addition, the stored data will be retained even after power to the device is removed. With these advantages, it has been broadly applied in personal computers and electronic equipment.

A typical flash memory device has a floating gate and a control gate fabricated using doped polysilicon. The control gate is set up above the floating gate with an inter-gate dielectric layer separating the two. Furthermore, a tunneling oxide layer is also set up between the floating gate and an underlying substrate (the so-called stack gate flash memory).

To write data into the flash memory, a bias voltage is applied to the control gate and the source/drain regions so that an electric field is set up to inject electrons into the floating gate. On the other hand, to read data from the flash memory, an operating voltage is applied to the control gate. Since the entrapment of charges inside the floating gate will directly affect the opening or closing of the underlying channel, the opening or closing of the channel can be construed as a data value of “1” or “0”. Finally, to erase data from the flash memory, the relative potential between the substrate and the drain (source) region or the control gate is raised. Hence, a tunneling effect can be utilized to transfer electrons from the floating gate to the substrate or drain (source) via the tunneling oxide layer (the so-called substrate erase or drain [source] side erase) or from the floating gate to the control gate via the inter-gate dielectric layer.

However, in the process of erasing data from the flash memory, the quantity of electrons expelled from the floating gate is difficult to control and hence often leads to the expulsion of too many electric charges from the floating gate, the so-called over-erasure. When the degree of over-erasure is severe, the channel underneath the floating gate may conduct even before an operating voltage is applied to the control gate. That means, erroneous data value may be read. To lessen the over-erasure problem, many types of flash memories have a split gate design. One major aspect of a split gate design is the inclusion of a select gate (or an erase gate) on the sidewall of the control gate and the floating gate above the substrate. The select gate (or erase gate) is isolated from the control gate, the floating gate and the substrate through an inter-gate dielectric layer. Hence, if the channel underneath the floating gate conducts even without the application of an operating voltage to the control gate due to serious over-erasure, the channel underneath the select gate (or the erase gate) can still be cut off to prevent any electrical connection between the source/drain regions. In other words, erroneous determination of data value can be prevented.

FIG. 1 is a schematic cross-sectional view of a conventional split-gate flash memory cell. As shown in FIG. 1, the flash memory cell is fabricated on a substrate 100. A tunneling oxide layer 102, a floating gate 104, an inter-gate dielectric layer 106 and a control gate 108 are sequentially formed over the substrate 100. A spacer 110 is formed on the sidewalls and top section of the control gate 106 and another spacer 112 is formed on the sidewall of the floating gate 104. The select gate 114 is set up on the sidewall on one side of the floating gate 104 and the control gate 106. A select gate oxide layer 116 is set up between the select gate 114 and the substrate 100. A source region 118 is set up in the substrate 100 on the side of the floating gate 104 and the control gate 106 where the select gate 114 is absent. The drain region 120 is set up in the substrate 100 on the side of the floating gate 104 and the control gate 106 where the select gate 114 is present.

To program the aforementioned flash memory cell, a 10V bias voltage is applied to the control gate 108, a 10V bias voltage is applied to the select gate 114, a 6V bias voltage is applied to the source region 118 and 0V is applied to the drain region 120. With this voltage setup, the programming is achieved through the migration of electrons from the drain region 120 to the source region 118 and the injection of electrons from the source region 118 into the floating gate 104. To erase data from the memory cell, a 0V is applied to the control gate 108 and a 10V to 12V bias voltage is applied to the select gate 114 while setting the source region 118 and the drain region 120 to a floating state. Hence, an electric field of considerable intensity is set up between the floating gate 104 and the select gate 114 so that the trapped electrons inside the floating gate 104 are pulled out and transferred to the select gate 114 through the Fowler-Nordheim (F-N) tunneling effect.

The aforementioned flash memory cell utilizes the select gate 114 both as a channel transistor and an erase gate. In other words, the select gate 114 serves as an erase gate during an erasing operation. If the select gate oxide layer has only a moderate thickness, substrate breakdown may occur during the erasing operation. Therefore, the select gate oxide layer 116 must have a thickness capable of preventing a possible substrate breakdown (for example, greater than 200Ã□). However, during a programming operation, the select gate 114 serves as the gate of a channel transistor. If the select gate oxide layer 116 is thick, a greater bias voltage will have to be applied to the select gate 114 just to turn on the channel transistor. In other words, the channel transistor has a high threshold voltage. Furthermore, the cell current flowing from the source terminal to the drain terminal will be reduced leading to a slowdown in the operating speed of the memory cell. On the other hand, if the channel transistor has a low threshold voltage, a greater thickness for the select gate oxide layer 116 will lead to a worsening of the channel control by the select gate and an increase in substrate leakage current. Since the memory cell has a high programming sensitivity, programming disturbance may occur with greater frequency.

### SUMMARY OF INVENTION

Accordingly, one object of the present invention is to provide a flash memory cell and a method of fabricating and operation the flash memory cell such that current running inside the memory device is increased and programming disturbance within the device is minimized. Hence, overall operating speed of the memory device is improved.

To achieve these and other advantages and in accordance with the purpose of the invention, as embodied and broadly described herein, the invention provides a flash memory cell structure. The flash memory cell includes a substrate, a tunneling dielectric layer over the substrate, a floating gate over the tunneling dielectric layer, an inter-gate dielectric layer over the floating gate, a control gate over the inter-gate dielectric layer, a first spacer on the sidewall and the top section of the control gate, a second spacer on the sidewall of the floating gate, a source region in the substrate on a first side of the control gate and the floating gate, an erase gate over a source region, an erase gate dielectric layer between the source region and the erase gate, a select gate on a second side of the control gate and the floating gate, a select gate dielectric layer between the substrate and the select gate and a drain region in the substrate on the side close to the select gate.

In the aforementioned flash memory cell, the erase gate dielectric layer has a thickness between about 200Ã□ to 250Ã58 . The select gate dielectric layer has a thickness between about 50Ã□ to 75Ã□ and the tunneling dielectric layer has a thickness between about 85Ã□ to 110Ã□.

In this invention, the erase gate is set up over the source region so that separate erase gate and the select gate are used inside the flash memory cell. Hence, the thickness of the select gate dielectric layer can be reduced while the thickness of the erase gate dielectric layer can be increased. Thus, there is no need to apply a high voltage to the select gate when the memory cell is programmed. Furthermore, due to the reduction in thickness of the oxide layer underneath the select gate, memory cell current can be increased when data are read from the memory so that a high operating speed is maintained. In addition, substrate breakdown is also prevented during a memory erase operation.

This invention also provides an alternative flash memory cell structure. The flash memory cell includes a substrate, a first gate structure and a second gate structure over the substrate with each gate structure having at least a floating gate over the substrate and a control gate over the floating gate, a source region in the substrate between the first gate structure and the second gate structure, an erase gate above the source region between the first gate structure and the second gate structure, an erase gate dielectric layer between the source region and the erase gate, a first select gate and a second select gate on the sidewall of the first gate structure and the second gate structure away from the source region, a select gate dielectric layer between the substrate and the first and the second select gate and a drain region in the substrate just outside the first select gate and the second select gate.

In the aforementioned flash memory cell, the erase gate dielectric layer has a thickness between about 200Ã□ to 250Ã□. The select gate dielectric layer has a thickness between about 50Ã□ to 75Ã□ and the tunneling dielectric layer has a thickness between about 85Ã□ to 110Ã□.

In this invention, the erase gate is set up over the source region between the first gate structure and the second gate structure so that separate erase gate and the select gate are used inside the flash memory cell. Hence, the thickness of the select gate dielectric layer can be reduced while the thickness of the erase gate dielectric layer can be increased. Thus, there is no need to apply a high voltage to the select gate when the memory cell is programmed. Furthermore, due to the reduction in thickness of the oxide layer underneath the select gate, memory cell current can be increased when data are read from the memory so that a high operating speed is maintained. In addition, substrate breakdown is also prevented during a memory erase operation. Moreover, with two neighboring gate structures using a single erase gate, there is no increase in the overall size of the flash memory cell.

This invention also provides a method of fabricating a flash memory cell. First, a substrate having a first gate structure and a second gate structure thereon is provided. The first gate structure and the second gate structure each includes a tunneling dielectric layer formed over the substrate, a floating gate formed over the tunneling dielectric layer, an inter-gate dielectric layer formed over the floating gate, a control gate formed over the inter-gate dielectric layer and a first spacer formed on the sidewall and top section of the control gate. Thereafter, a source region is formed in the substrate between the first gate structure and the second gate structure. An erase gate dielectric layer is formed over the surface of the source region. A second spacer is formed on the sidewall of the floating gate. An erase gate is formed over the source region such that the erase gate fills up the space between the first gate structure and the second gate structure. After forming a third spacer on the sidewall on one side of the first and the second gate structures, a select gate dielectric layer is formed over the substrate. Next, a first select gate and a second select gate are formed on the sidewall of the third spacers. Finally, a first drain region and a second drain region are formed in the substrate on one side of the first select gate and the second select gate.

In the aforementioned method of fabricating the memory cell, the first gate structure and the second gate structure are formed before forming a first dielectric layer, a first conductive layer and a second dielectric layer sequentially over the substrate. Thereafter, a second conductive layer is formed over the second dielectric layer and then the second conductive layer is patterned to form the control gate. Next, a first spacer is formed on the sidewalls and the top section of the control gate. Using the first spacer and the control gate as a mask, the second dielectric layer, the first conductive layer, the first dielectric layer are patterned to form an inter-gate dielectric layer, a floating gate and a tunneling dielectric layer.

In this invention, a conductive layer is formed over a source region to fabricate the erase gate so that the erase gate and the select gate are separate devices. Hence, the erase gate dielectric layer can have a greater thickness (for example, greater than 200Ã□) while the select gate dielectric layer underneath the select gate can be thinner (for example, about 65Ã□). As a result, the threshold voltage for triggering the memory device is reduced and cell current flowing inside the memory device is increased. In addition, programming disturbance is minimized so that the memory cell can operate faster. Moreover, with a thicker erase gate dielectric layer, substrate breakdown during an erasing operation is prevented.

This invention also provides a method of operating a flash memory cell. The flash memory cell includes a substrate, a floating gate over the substrate, a floating gate over the control gate, a source region in the substrate on a first side of the control gate and the floating gate, an erase gate over the source region on a first side of the control gate and the floating gate, a select gate on the sidewall on a second side of the control gate and the floating gate and a drain region in the substrate on one side of the select gate. The channel hot electron injection effect are induced to program data into the flash memory cell by applying a first positive voltage to the control gate, a second positive voltage to the select gate, a third positive voltage to the source region and maintaining the drain region is in a floating state. The Fowler-Nordheim tunneling effect is induced to erase data from the flash memory cell by applying a fourth positive voltage to the erase gate, setting the control gate to 0V and maintaining both the source region and the drain region in a floating state.

In the aforementioned method of operating the flash memory cell, electrons are removed through the erase gate instead of select gate. Hence, the erase gate dielectric layer can have a greater thickness (for example, greater than 200Ã□) while the select gate dielectric layer underneath the select gate can be thinner (for example, about 65Ã□). In other words, a smaller threshold voltage can be used to trigger the memory device and a larger cell current can be used for the programming so that programming disturbance is minimized and operating speed of the memory cell is increased. Furthermore, with a thicker erase dielectric layer, substrate breakdown during an erase operation can be prevented.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view of a conventional split-gate flash memory cell.

FIG. 2 is a schematic cross-sectional view of a flash memory cell according to one preferred embodiment of this invention.

FIGS. 3A to 3F are schematic cross-sectional views showing the progression of steps for fabricating a flash memory cell according to one preferred embodiment of this invention.

FIG. 4A is a schematic cross-sectional view of a flash memory cell showing the method of programming data into the flash memory cell according to this invention.

FIG. 4B is a schematic cross-sectional view of a flash memory cell showing the method of erasing data from the flash memory cell according to this invention.

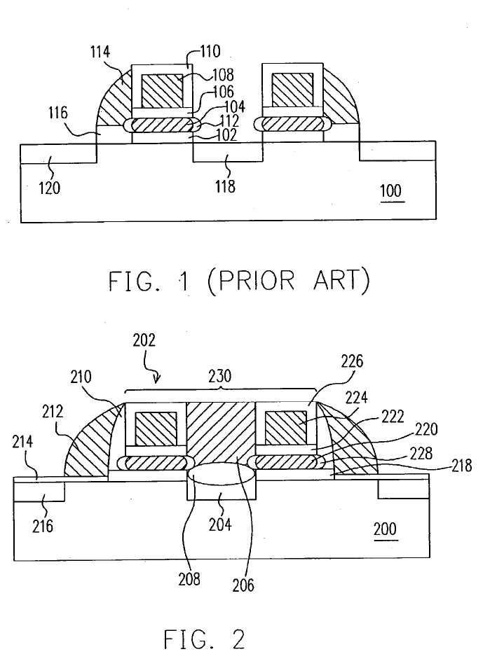

### DETAILED DESCRIPTION

Reference will now be made in detail to the present preferred embodiments of the invention, examples of which are illustrated in the accompanying drawings. Wherever possible, the same reference numbers are used in the drawings and the description to refer to the same or like parts.

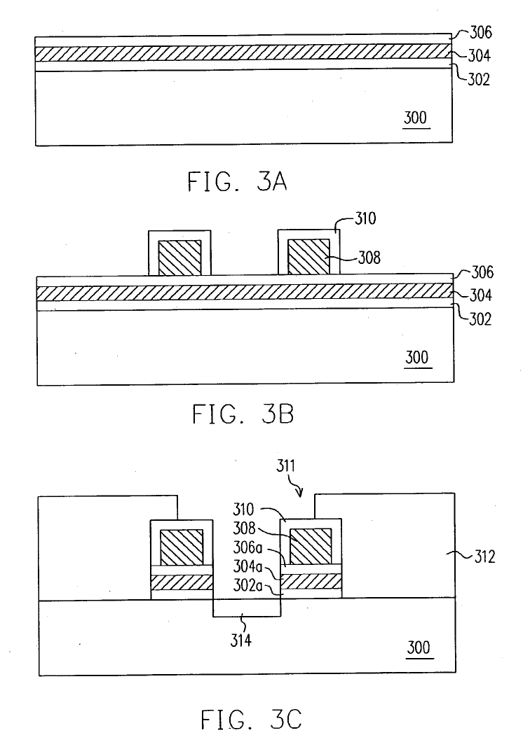

FIG. 2 is a schematic cross-sectional view of a flash memory cell according to one preferred embodiment of this invention. As shown in FIG. 2, the flash memory cell includes a substrate 200, a gate structure 202, a source region 204, an erase gate 206, an erase gate dielectric layer 208, a spacer 210, a select gate 212, a select gate dielectric layer 214 and a drain region 216.

The gate structure 202 is set up over the substrate 200. The gate structure 202 includes a tunneling oxide layer 218, a floating gate 220, an inter-gate dielectric layer 222, a control gate 224 and spacers 226, 228. Furthermore, each pair of neighboring gate structures 202 constitutes a composite gate structure 230. The tunneling oxide layer 218 is formed over the substrate 200. The floating gate is formed over the tunneling oxide layer 218. The inter-gate dielectric layer 222 is formed over the floating gate 220. The control gate 224 is formed over the inter-gate dielectric layer 222. The spacer 226 is formed on the sidewalls and the top section of the control gate 224. The spacer 228 is formed on the sidewalls of the floating gate 220.

The source region 204 is formed in the substrate 200 (in the substrate 200 on one side of the gate structure 202) within a composite gate structure 230. The erase gate 206 is formed over the source region 204 between the two gate structures of the composite gate structure 230. The erase gate dielectric layer 208 is formed between the erase gate 206 and the source region 204. The erase gate dielectric layer 208 having a thickness greater than about 200Ã□ is a silicon oxide layer, for example. The spacer 210 is formed on the sidewalls of the composite gate structure 230 (that is, the sidewall of the gate structure 202 away from the erase gate 206). The select gate 212 is formed on the sidewall of the spacer 210. The select gate dielectric layer 212 is formed between the select gate 212 and the substrate 200. The select gate dielectric layer 212, having a thickness between 50Ã□ to 70Ã□, is a silicon oxide layer, for example. The drain region 216 is formed in the substrate 200 on one side of the select gate 212.

In the aforementioned flash memory cell, an additional erase gate 206 is set up over the source region 204 so that the erase gate 206 and the select gate 212 are separate members. Therefore, thickness of the select gate dielectric layer 214 underneath the select gate 212 can be reduced while the erase gate dielectric layer 208 underneath the erase gate 206 can be increased. As a result, a smaller voltage can be applied to the select gate 212 to program data into the memory cell at a normal operating speed and substrate breakdown during a memory erasing operation can be prevented. Moreover, with each pair of neighboring gate structures 202 (memory cells) using the same erase gate 206, there is no additional size increase in the memory cell of this invention.

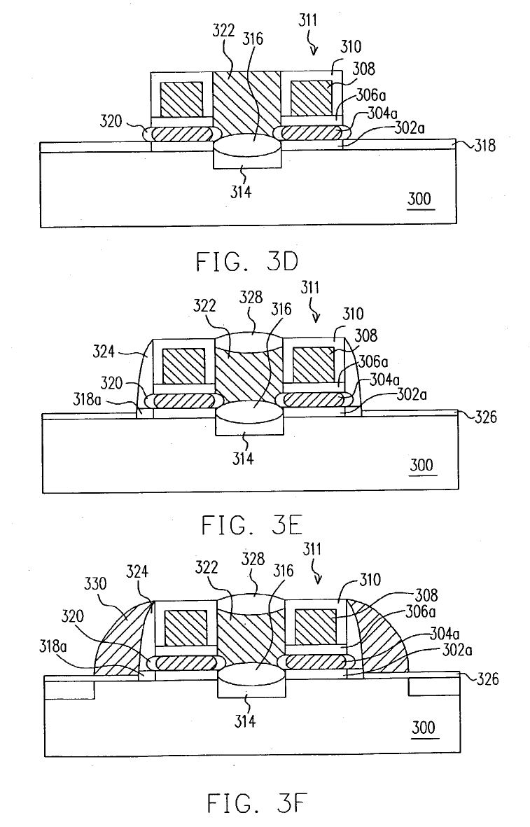

FIGS. 3A to 3F are schematic cross-sectional views showing the progression of steps for fabricating a flash memory cell according to one preferred embodiment of this invention. As shown in FIG. 3A, a substrate 300 is provided. Thereafter, a tunneling dielectric layer 302 is formed over the substrate 300. The tunneling dielectric layer 302 is a silicon oxide layer formed, for example, by performing a thermal oxidation process. The tunneling dielectric layer 302 preferably has a thickness between about 85Ã□˜110Ã□.

Thereafter, a conductive layer 304 is formed over the tunneling dielectric layer 302. The conductive layer 304 is a doped polysilicon layer formed, for example, by performing a chemical vapor deposition process to form an undoped polysilicon layer and then performing an ion implantation process to transformed the undoped polysilicon layer into the doped polysilicon layer. The conductive layer 304 preferably has a thickness about 200Ã□. Arsenic ions, for example, are used to form the implanted conductive layer 204 so that easy-to-erase circular structures are formed in a subsequent thermal oxidation process. Next, an inter-gate dielectric layer 306 is formed over the substrate 300. The inter-gate dielectric layer 306 is, for example, an oxide/nitride/oxide composite layer with the lower oxide layer having a thickness between 60Ã□ to 100Ã□, the middle nitride layer having a thickness between 70Ã□ to 100Ã□ and the upper oxide layer having a thickness between 60Ã□ to 100Ã□. To form the inter-gate dielectric layer 306, for example, a thermal oxidation process is performed to form a silicon oxide layer over the substrate 300. Thereafter, a chemical vapor deposition process is performed to deposit a silicon nitride layer over the silicon oxide layer. Finally, a wet hydrogen/oxygen (H₂/O₂) gaseous mixture is blown over the nitride layer to oxidize a portion of the nitride layer into another silicon oxide layer over the nitride layer. Obviously, the inter-gate dielectric layer 306 can be a silicon oxide layer or an oxide/nitride composite layer as well.

As shown in FIG. 3B, a conductive layer (not shown) is formed over the substrate 300. Thereafter, using a mask, the conductive layer is patterned to form a conductive layer 308 that serves as a control gate. The conductive layer 308 is a doped polysilicon layer formed, for example, by performing a chemical vapor deposition process with in-situ ion doping. After removing the mask, an insulating layer 310 (a spacer) is formed on the sidewalls and the top section of the conductive layer 308. The insulating layer 310 (the spacer) is a silicon oxide layer formed, for example, by performing a thermal oxidation process.

As shown in FIG. 3C, using the conductive layer 308 and the insulating layer 310 (the spacer) as a mask, the inter-gate dielectric layer 306, the conductive layer 304 and the tunneling dielectric layer 302 are patterned to form an inter-gate dielectric layer 306a, a conductive layer 304a and a tunneling dielectric layer 302a. The conductive layer 304a serves as a floating gate. The conductive layer (the control gate) 308, the inter-gate dielectric layer 306a, the conductive layer (the floating gate) 304a and the oxide layer 302 (the tunneling oxide layer) together form a gate structure 311. Thereafter, a patterned mask layer 312 is formed over the substrate 300 globally. The patterned mask layer 312 exposes a portion of the substrate 300 for forming a source region 314. Using the patterned mask layer 312 as a mask, an ion implantation is carried out implanting dopants into the substrate 300 to form the source region 314. In general, each pair of neighboring gate structures 311 can be regarded as a composite gate so that the source region 314 is located between the individual gate structure 311 of the pair.

As shown in FIG. 3D, the patterned mask layer 312 is removed. Thereafter, an erase gate dielectric layer 316 is formed over the source region 314 between two gate structures 311, a dielectric layer 318 is formed over the substrate 300 and an insulating layer (a spacer) 320 is formed on the sidewall of the conductive layer 304a (the floating gate). The erase gate dielectric layer 316, the dielectric layer 318 and the insulating layer (the spacer) 320 are silicon oxide layers formed, for example, by performing a thermal oxidation process. The erase gate oxide layer 316 has a thickness greater than 200Ã□, preferably between about 200Ã□ to 250Ã□. Next, a conductive layer 322 is formed over the source region 314 (that is, between the gate structures 311). The conductive layer 322 serves as an erase gate. The conductive layer 322 is a doped polysilicon layer formed, for example, by performing a chemical vapor deposition process with in-situ ion doping to form a conductive layer (not shown) over the substrate 300 and then removing excess conductive material outside the space between the gate structures 311.

As shown in FIG. 3E, a spacer 324 is formed on the sidewall of the gate structure 311 away from the conductive layer 322. The spacer 324 is formed, for example, by forming a high temperature oxide (HTO) having a thickness between 150Ã□ to 400Ã□ and then performing an anisotropic etching process to remove a portion of the HTO layer. Only a portion of the dielectric layer 318 is retained to form a dielectric layer 318a when the spacer 324 is formed. However, the dielectric layer 318a can be regarded as a portion of the spacer 324. Thereafter, a select gate dielectric layer 326 is formed over the substrate 300 and then an insulating layer 328 is formed on the top section of the conductive layer 322. The select gate dielectric layer 326 is a silicon oxide layer having a thickness between 50Ã□ to 70Ã□, for example. The select gate dielectric layer 326 and the insulating layer 328 are formed, for example, by performing a thermal oxidation process.

As shown in FIG. 3F, a conductive layer 330 is formed on the sidewall of the gate structures 311 away from the conductive layer 322. The conductive layer 320 is a doped polysilicon layer formed, for example, by performing a chemical vapor deposition process with in-situ ion doping to form a conductive layer (not shown) over the substrate 300 and then performing an anisotropic etching process to remove a portion of the conductive layer. Thereafter, using the gate structures 311 and the conductive layers 330 as a mask, an ion implantation is carried out implanting dopants into the substrate 300 to form a drain region 332 on one side of the conductive layer 330. Finally, other operations necessary for completing the flash memory cell fabrication are carried through. Since conventional processes are used, a detailed description of these operations is omitted here.

In the aforementioned embodiment of this invention, a conductive layer 322 is formed over a source region 314 to fabricate the erase gate so that the erase gate and the select gate are separate devices. Hence, the erase gate dielectric layer 316 can have a greater thickness (for example, greater than 200Ã□) while the select gate dielectric layer 326 underneath the select gate can be thinner (for example, about 65Ã□). As a result, threshold voltage for triggering the memory device is reduced and cell current flowing inside the memory device is increased. In addition, programming disturbance is minimized so that the memory cell can operate faster. Moreover, with a thicker erase gate dielectric layer, substrate breakdown during an erasing operation is prevented.

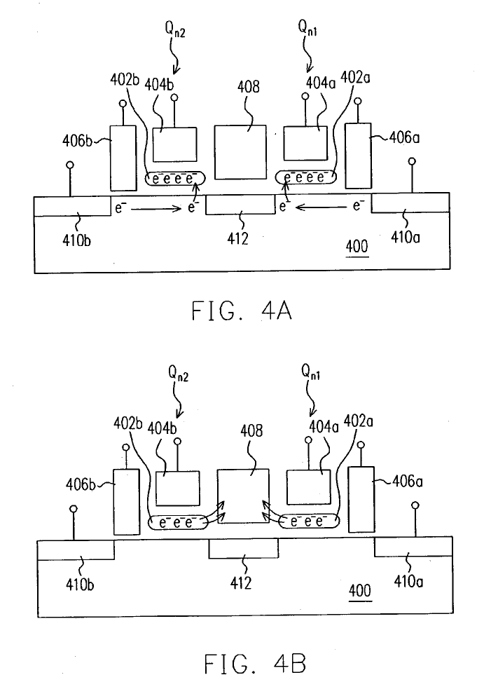

FIGS. 4A and 4B are a schematic cross-sectional views of a flash memory cell showing two methods of operating the flash memory cell according to this invention. FIG. 4A shows a method of programming data into the flash memory cell and FIG. 4B shows a method of erasing data from the flash memory cell.

To program the memory cell Qn1, for example, a bias voltage of about 10V is applied to the select gate 406a to open up the channel underneath the select gate 406a, a positive bias voltage VCGₚ within the range 10V to 12V is applied to the control gate 404a, a positive bias voltage VSₚ of about 6V is applied to the source region 412 and the drain region 410a is grounded. With this voltage setup, electrons move from the drain region 410a to the source region 412 and get accelerated by the high channel field at the source region 412 terminal to produce hot electrons. Thus, the electrons received enough kinetic energy to overcome the energy barrier of the tunneling dielectric layer. Together with the positive bias voltage applied to the control gate 404a, the hot electrons are injected from the source region 412 terminal into the floating gate 402a and hence programmed the memory cell Qn1. Similarly, to program the memory cell Qn2, a bias voltage of about 10V is applied to the select gate 406b to open up the channel underneath the select gate 406b, a positive bias voltage VCGₚ within the range 10V to 12V is applied to the control gate 404b, a positive bias voltage VSₚ of about 6V is applied to the source region 412 and the drain region 410b is grounded. With this voltage setup, electrons move from the drain region 410b to the source region 412 and are accelerated by the high channel field at the source region 412 terminal to produce hot electrons. Thus, the electrons received enough kinetic energy to overcome the energy barrier of the tunneling dielectric layer. Together with the positive bias voltage applied to the control gate 404b, the hot electrons are injected from the source region 412 terminal into the floating gate 402b and hence programmed the memory cell Qn2.

To erase data from the memory cells Qn1, Qn2, a 0V is applied to the control gate 404a and the control gate 404b, a positive bias voltage VSGE within the range 10V to 12V is applied to the erase gate 408 and setting the source region 412, the drain regions 410a, 410b in a floating state. With this voltage setup, an intense electric field is built up between the floating gates 402a, 402b and the erase gate 408 so that electrons are pulled out from the floating gates 402a, 402b to the erase gate 408 through the Fowler-Nordheim effect as shown in FIG. 4B.

In the aforementioned embodiment, electrons are removed by way of the erase gate 408 instead of the select gate 406a or the select gate 406b. Hence, an erase gate dielectric layer having a greater thickness (greater than 200Ã□) can be used wile a select gate dielectric layer having a smaller thickness (around 65Ã□) can be used underneath the select gates 406a, 406b. In other words, a smaller threshold voltage can be used to trigger the memory device and a larger cell current can be used for the programming so that programming disturbance is minimized and operating speed of the memory cell is increased. Furthermore, with a thicker erase dielectric layer, substrate breakdown during an erase operation can be prevented.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A flash memory cell, comprising:
a substrate;
a tunneling dielectric layer formed over the substrate;
a floating gate formed over the tunneling dielectric layer;
an inter-gate dielectric layer formed over the floating gate;
a control gate formed over the inter-gate dielectric layer;
a first spacer layer formed on the sidewalls and the top section of the control gate;
a pair of second spacers formed on the sidewalls of the floating gate;
a source region formed in the substrate on a first side of the control gate and the floating gate;
an erase gate formed on the source region;
an erase gate dielectric layer formed between the source region and the erase gate;
a select gate formed on a second side of the control gate and the floating gate;
a select gate dielectric layer formed between the substrate and the select gate; and
a drain region formed in the substrate on one side of the select gate.

2. The flash memory cell of claim 1, wherein the erase gate dielectric layer has a thickness between about 200Ã□ to 250Ã□.

3. The flash memory cell of claim 1, wherein the select gate dielectric layer has a thickness between about 50Ã□ to 75Ã□.

4. The flash memory cell of claim 1, wherein the tunneling dielectric layer has a thickness between about 85Ã□ to 110Ã□.

5. The flash memory cell of claim 1, wherein the cell further comprises a third spacer formed between the select gate and the control gate as well as between the select gate and the floating gate.

6. A flash memory cell, comprising:
a substrate;
a first gate structure and a second gate structure formed on the substrate, wherein the first gate structure and the second gate structure each has at least a floating gate formed over the substrate and a control gate formed over the floating gate;
a source region formed in the substrate between the first gate structure and the second gate structure;
an erase gate formed above the source region between the first gate structure and the second gate structure;
an erase gate dielectric layer formed between the source region and the erase gate;
a first select gate and a second select gate formed on one side of the sidewall of the first gate structure and the second gate structure away from the source region;
a select gate dielectric layer formed between the substrate and the first and second select gate; and
a pair of drain regions formed in the substrate just outside the first select gate and the second select gate.

7. The flash memory cell of claim 6, wherein the erase gate dielectric layer has a thickness between about 200Ã□ to 250Ã□.

8. The flash memory cell of claim 6, wherein the select gate dielectric layer has a thickness between about 50Ã□ to 75Ã□.

9. The flash memory cell of claim 6, wherein each of the first gate structure and the second gate structure further comprises:
a tunneling dielectric layer formed between the floating gate and the substrate;
an inter-gate dielectric layer formed between the control gate and the floating gate;
a first spacer layer formed on the sidewalls and the top section of the control gate; and
a pair of second spacers formed on the sidewalls of the floating gate.

10. The flash memory cell of claim 9, wherein the tunneling dielectric layer has a thickness between about 85Ã□ to 110Ã□.

11. A method of fabricating flash memory cells, comprising the steps of:
providing a substrate, wherein the substrate has a first gate structure and a second gate structure thereon, the first gate structure and the second gate structure each comprises a tunneling dielectric layer formed over the substrate, a floating gate formed over the tunneling dielectric layer, an inter-gate dielectric layer formed over the floating gate, a control gate formed over the inter-gate dielectric layer and a first spacer formed on the sidewalls and the top section of the control gate;
forming a source region in the substrate between the first gate structure and the second gate structure;
forming an erase gate dielectric layer over the upper surface of the source region and forming a second spacer on the sidewalls of the floating gate;
forming an erase gate over the source region such that the erase gate completely fills the space between the first gate structure and the second gate structure;
forming third spacers on the other sides of the first gate structure and the second gate structure corresponding the erase gate;
forming a select gate dielectric layer over the substrate;
forming a first select gate and a second select gate on the sidewall of the third spacers; and
forming a first drain region and a second drain region in the substrate just outside the first select gate and the second select gate.

12. The method of claim 11, wherein the step of forming the first gate structure and the second gate structure furthermore includes:
forming a first dielectric layer over the substrate;
forming a first conductive layer over the dielectric layer;
forming a second dielectric layer over the first conductive layer;
forming a second conductive layer over the second dielectric layer;
patterning the second conductive layer to form the control gate;
forming the first spacer layer on the sidewalls and the top section of the control gate; and
patterning the second dielectric layer, the first conductive layer, the first dielectric layer to form the inter-gate dielectric layer, the floating gate and the tunneling dielectric layer using the first spacer layer and the control gate as a mask.

13. The method of claim 11, wherein the step of forming the erase gate dielectric layer over the source region and a pair of second spacers on the sidewalls of the floating gate includes performing a thermal oxidation process.

14. The method of claim 11, wherein the erase gate dielectric layer has a thickness between about 200Ã□ to 250Ã□.

15. The method of claim 11, wherein the select gate dielectric layer has a thickness between about 50Ã□ to 75Ã□.

16. The method of claim 11, wherein the tunneling dielectric layer has a thickness between about 85Ã□ to 110Ã□.

17. The method of claim 11, wherein the step of forming the select gate dielectric layer over the substrate further comprises a step of forming an insulating layer over the erase gate.

18. The method of claim 17, wherein the step of forming the select gate dielectric layer over the substrate comprises performing a thermal oxidation process.

19. The method of claim 11, wherein the floating gate includes arsenic doped polysilicon layer.

20. A method of operating a flash memory cell, wherein the flash memory cell comprises a substrate, a floating gate formed over the substrate, a control gate formed over the floating gate, a source region formed in the substrate on a first side of the control gate and the floating gate, an erase gate formed above the source region on the firs side of the control gate and the floating gate, a select gate formed on a second side of the sidewall of the control gate and the floating gate, a drain region formed in the substrate just outside the select gate, the operating method comprising the steps of:
applying a first positive voltage to the control gate, applying a second positive voltage to the select gate, applying a third positive voltage to the source region and connecting the drain region to ground so that channel hot electrons are injected to program data into the flash memory cell; and
applying a fourth positive voltage to the erase gate, setting the control gate to 0V and setting the source region and the drain region to a floating state so that the Fowler-Nordheim effect is triggered to erase data from the flash memory cell.
